(19) United States
(12) Patent Application Publication
(10) Pub. No.: US 2026/0173644 A1
(43) Pub. Date: Jun. 18, 2026

(54) Display Device

(71) Applicant: LG Display Co., Ltd., Seoul (KR)

(72) Inventor: Namseok Yoo, Paju-si (KR)

(21) Appl. No.: 19/361,354

(22) Filed: Oct. 17, 2025

(30) Foreign Application Priority Data
Dec. 12, 2024 (KR) 10-2024-0185013

(51) Int. Cl. H10K 50/14; H10K 59/122

(52) U.S. Cl. CPC H10K 50/14; H10K 59/122

(57) ABSTRACT

A display device is provided, comprising an n-type charge generation layer including a doped region including an n-type dopant material and an undoped region not including the n-type dopant material, wherein the doping prevention layer does not overlap with the doped region and overlaps with the undoped region.

### CROSS-REFERENCE TO RELATED APPLICATIONS

This application claims priority under 35 U.S.C. §119(a) to the Republic of Korea Patent Application No. 10-2024-0185013, filed on December 12, 2024, the entire contents of which are hereby expressly incorporated by reference into the present application.

### TECHNICAL FIELD

The present disclosure relates to a display device.

### BACKGROUND

As an information society develops, a demand for a display device for displaying an image is increasing in various forms. Accordingly, various display devices such as a liquid crystal display (LCD), a plasma display panel (PDP), and an organic light emitting display (OLED) have recently been used.

Among the display devices, the organic light emitting display device is a self-luminous type, has better viewing angle and contrast ratio than the liquid crystal display (LCD), and has an advantage of being lightweight and thin because a separate backlight is not required, and power consumption is advantageous. In addition, the organic light emitting display device has an advantage of being driven with a low DC voltage, having a fast response speed, and especially low manufacturing cost.

Recently, as a high-resolution display device is implemented, a distance between pixels has been reduced. Accordingly, a lateral leakage current (LLC) flows between neighboring pixels, and a display quality is deteriorated.

### SUMMARY

The present disclosure has been made in view of the above problems and it is an aspect of the present disclosure to provide a display device with reduced generation of a lateral leakage current.

In accordance with an aspect of the present disclosure, the above and other technical effects can be accomplished by the provision of a display device comprising a plurality of sub-pixels including an emission area and a non-emission area surrounding the emission area, and each of the plurality of sub-pixels include a first electrode disposed on the substrate in the emission area, a first stack disposed on the first electrode, a doping prevention layer disposed on the first stack, and an n-type charge generation layer disposed on the doping prevention layer, wherein the n-type charge generation layer includes a doped region including an n-type dopant material and an undoped region not including the n-type dopant material, and wherein the doping prevention layer does not overlap the doped region and overlaps the undoped region.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description explain the principle of the disclosure. In the drawings:

FIG. 1 is a plan view of a display device according to an embodiment of the present disclosure.

FIG. 2 is a plan view of one pixel according to an embodiment of the present disclosure.

FIG. 3 is a cross-sectional view of one sub-pixel according to an embodiment of the present disclosure.

FIG. 4 is an enlarged view of an area C of FIG. 3.

FIG. 5 is a cross-sectional view of one pixel according to an embodiment of the present disclosure.

FIG. 6 is an enlarged view of an area D of FIG. 5.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and implementation methods thereof, will be clarified through the following examples described with reference to the accompanying drawings. The present disclosure may, however, be embodied in different forms and should not be construed as limited to the examples set forth herein. Rather, these examples are provided so that the specification of the present disclosure will be thorough, complete, and fully convey the scope of the present disclosure to those skilled in the art. Further, the scope of the present disclosure is only defined by that of the accompanying claims.

A shape, a size, a ratio, an angle, and a number disclosed in the accompanying drawings for describing the examples of the present disclosure are merely illustrative and, thus, the present disclosure is not limited to the illustrated details. Unless stated otherwise, like reference numerals refer to like elements throughout the specification. In the following description, when the detailed description of the relevant known function or configuration is determined to unnecessarily obscure an important point of the present disclosure, the detailed description will be omitted. In a case where ‘comprise’, ‘have’, and ‘include’ described in the present disclosure are used, another portion may be added unless ‘only~’ is used. The terms of a singular form may include plural forms unless referred to the contrary.

In interpreting the components, it is interpreted as including an error range even if there is no separate explicit description of an error range.

In describing a position relationship, for example, when the position relationship is described as ‘upon~’, ‘above~’, ‘below~’ and ‘next to~’, one or more portions may be disposed between two other portions unless ‘just’ or ‘direct’ is used. The terms, such as “below,” “lower,” “above,” “upper”, and the like, may be used herein to describe a relationship between elements as illustrated in the drawings. It will be understood that the terms are spatially relative and based on the orientation depicted in the drawings.

A description of a time relationship may include a case in which the temporal precedence relationship is described as “after”, “following”, or “before”, etc., and is not continuous unless “right away” or “directly”, is used.

Although the first, second, and the like are used to describe various components, these components are not limited by these terms. These terms are used only to distinguish one component from another. Therefore, a first component mentioned below may be a second component within a technical idea of a present disclosure.

It will be understood that, although the terms “first,” “second,” “A,” “B,” “(a),” and “(b)”, etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of each of the various examples of the present disclosure may be partially or entirely coupled or combined with each other, technically various interworking and driving are possible, and each of the examples may be independently implemented with respect to each other or may be implemented together in a related relationship.

Hereinafter, one embodiment of the present disclosure will be described in detail with reference to the accompanying drawings.

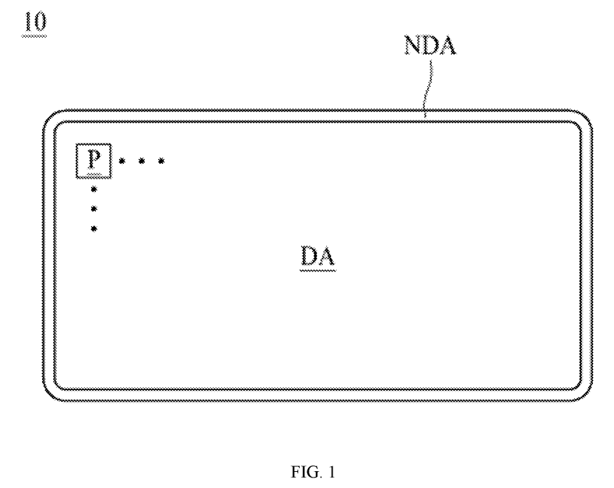

FIG. 1 is a plan view of a display device according to an embodiment of the present disclosure.

Referring to FIG. 1, the display device 10 according to an embodiment of the present disclosure may include a display area DA and a non-display area NDA surrounding the display area DA. The display area DA is an area in which an image may be displayed, and the non-display area NDA is an area in which an image is not displayed.

The display area DA may include a plurality of pixels P. The plurality of pixels P may be arranged in a matrix form consisting of a plurality of rows and columns. In addition, the non-display area NDA may include a plurality of wirings, pads, driving circuits, etc. for driving the plurality of pixels P.

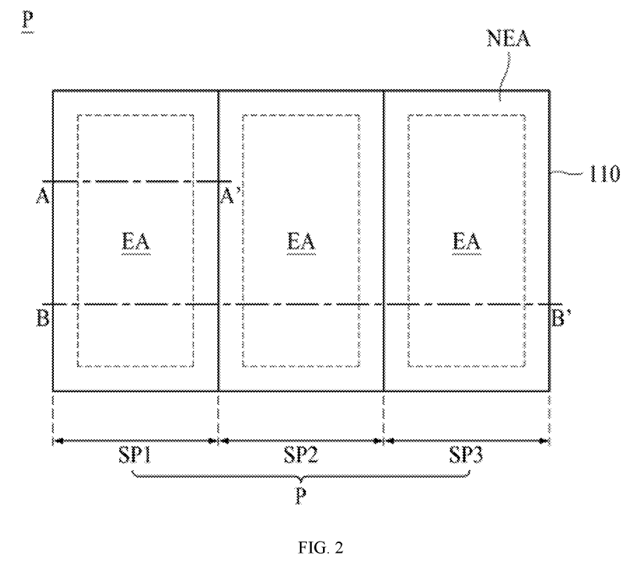

FIG. 2 is a plan view of one pixel according to an embodiment of the present disclosure.

Referring to FIG. 2, one pixel P may include a first sub-pixel SP1, a second sub-pixel SP2, and a third sub-pixel SP3. The first sub-pixel SP1, the second sub-pixel SP2, and the third sub-pixel SP3 may emit different light from each other. For example, the first sub-pixel SP1 may emit red light, the second sub-pixel SP2 may emit green light, and the third sub-pixel SP3 may emit blue light, but the present disclosure is not limited thereto. In addition, FIG. 2 shows that one pixel P includes three sub-pixels SP1 to SP3, but is not limited thereto. For example, one pixel P may include more than three sub-pixels.

The first sub-pixel SP1, the second sub-pixel SP2, and the third sub-pixel SP3 may be disposed on a first substrate 110. Each of the first sub-pixel SP1, the second sub-pixel SP2, and the third sub-pixel SP3 may include an emission area EA and a non-emission area NEA surrounding the emission area EA. The emission area EA is an area capable of emitting light, and the non-emission area NEA is an area that does not emit light.

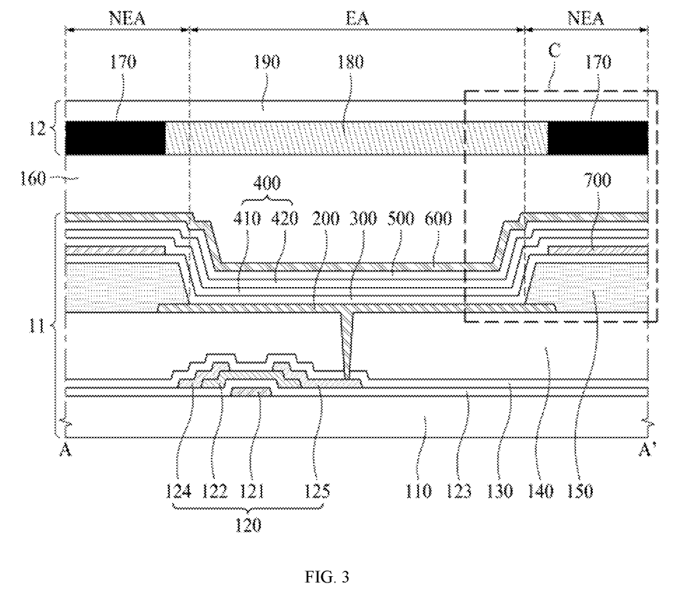

FIG. 3 is a cross-sectional view of one sub-pixel SP according to a first embodiment of the present disclosure. In detail, FIG. 3 is a cross-sectional view of one sub-pixel SP taken along line A-A′ illustrated in FIG. 2. FIG. 3 illustrates a cross-sectional view of the first sub-pixel SP1, but the present disclosure is not limited thereto. For example, FIG. 3 may be a cross-sectional view of any one of the second sub-pixel SP2 and the third sub-pixel SP3 illustrated in FIG. 2.

Referring to FIG. 3, one sub-pixel SP according to an embodiment of the present disclosure may include a circuit unit 11 and a filter unit 12. The circuit unit 11 may include a first substrate 110, a thin film transistor 120, a passivation layer 130, a planarization layer 140, a bank 150, and a light emitting device OLED. The filter unit 12 may include a black matrix 170, a color filter 180, and a second substrate 190. The circuit unit 11 and the filter unit 12 may be bonded to each other by an encapsulation layer 160.

The first substrate 110 may be made of glass or plastic, but is not limited thereto. The display device according to an embodiment of the present disclosure may be configured in a top emission type in which light is emitted upward. Therefore, as a material of the first substrate 110, not only a transparent material but also an opaque material may be used.

The thin film transistor 120 may be disposed on the first substrate 110. The thin film transistor 120 may include a gate electrode 121, a semiconductor layer 122, a gate insulating layer 123, a source electrode 124, and a drain electrode 125.

The gate electrode 121 of the thin film transistor 120 may be disposed on the first substrate 110. In addition, the semiconductor layer 122 may be disposed on the gate electrode 121. The semiconductor layer 122 may include a poly-silicon semiconductor or an oxide semiconductor. In addition, when the semiconductor layer 122 includes the oxide semiconductor, at least one oxide of indium-gallium-zinc-oxide (IGZO), indium-gallium-tin-oxide (IGTO), and indium-gallium-oxide (IGO) may be included.

The gate insulating layer 123 for insulating the gate electrode 121 and the semiconductor layer 122 may be disposed between the gate electrode 121 and the semiconductor layer 122. The gate insulating layer 123 may be formed of a single layer of silicon nitride (SiNₓ) or silicon oxide (SiOₓ), or multiple layers thereof. In addition, FIG. 3 illustrates a bottom gate structure in which the semiconductor layer 122 is disposed on the gate electrode 121, but is not limited thereto. For example, a top gate structure in which the gate electrode 121 is disposed on the semiconductor layer 122 may be disclosed.

The source electrode 124 and the drain electrode 125 may be disposed on the semiconductor layer 122 while facing each other. In addition, the passivation layer 130 may be disposed on the source electrode 124 and the drain electrode 125. A contact hole exposing a portion of the drain electrode 125 may be disposed in the passivation layer 130. In addition, the passivation layer 130 may be formed of an inorganic insulating material such as silicon oxide (SiOₓ), silicon nitride (SiNₓ), silicon oxynitride (SiOₓN_{y}), or the like.

The planarization layer 140 may be disposed on the thin film transistor 120. The planarization layer 140 may compensate for a step difference caused by the thin film transistor 120 to form a flat upper area of the thin film transistor 120. In addition, the planarization layer 140 may be formed of an organic insulating material such as an acrylic resin, an epoxy resin, a phenolic resin, a polyamide resin, or a polyimide resin.

The bank 150 may be disposed on the planarization layer 140 and in the non-emission area NEA. The bank 150 may expose a partial area of the planarization layer 140.

The bank 150 may include an organic insulating material such as an acrylic resin, an epoxy resin, a phenolic resin, a polyamide resin, a polyimide resin, etc. Alternatively, the bank 150 may include an inorganic insulating material such as silicon oxide (SiOₓ), silicon nitride (SiNₓ), silicon oxynitride (SiOₓN_{y}), etc. In this case, the bank 150 may further include a material absorbing light. For example, the bank 150 may be black bank.

The light emitting device OLED may be disposed on the planarization layer 140. The light emitting device OLED may include a first electrode 200, a first stack 300, a charge generation layer 400, a second stack 500, and a second electrode 600.

The first electrode 200 may be disposed on the planarization layer 140 exposed by the bank 150. An end of the first electrode 200 may be covered by the bank 150. In addition, the first electrode 200 may function as an anode of the display device. That is, the first electrode 200 may provide holes to the first stack 300.

The first electrode 200 may be electrically connected to the thin film transistor 120 through a contact hole disposed in the passivation layer 130 and the planarization layer 140. Although FIG. 3 illustrates that the first electrode 200 is electrically connected to the drain electrode 125, the present disclosure is not limited thereto. For example, the first electrode 200 may be electrically connected to the source electrode 124.

The first electrode 200 may include a transparent conductive material such as indium tin oxide (ITO) or indium zinc oxide (IZO). Alternatively, the first electrode 200 may include a metal material such as aluminum (Al), silver (Ag), copper (Cu), molybdenum (Mo), titanium (Ti), tungsten (W), or chromium (Cr), or an alloy thereof. Furthermore, the first electrode 200 is illustrated as a single layer, but may be formed as multiple layers.

The first stack 300 may be disposed on the first electrode 200. The first stack 300 may also be disposed on the bank 150. That is, the first stack 300 may be disposed in the emission area EA and the non-emission area NEA.

The first stack 300 may include a first emission layer. The first emission layer may generate light. For example, the first emission layer may generate any one of red, green, and blue light, but is not limited thereto.

The first stack 300 may further include a material layer for assisting the first emission layer to generate light. For example, the first stack 300 may include a first hole transport layer, a first electron transport layer, or the like. The first hole transport layer may assist holes provided in the first electrode 200 to be easily transported to the first emission layer. In addition, the first electron transport layer may assist electrons provided in the charge generation layer 400 to be easily transported to the first emission layer.

The charge generation layer 400 may be disposed on the first stack 300. Like the first stack 300, the charge generation layer 400 may also be disposed on the bank 150. That is, the charge generation layer 400 may be disposed in the emission area EA and the non-emission area NEA.

The charge generation layer 400 may include an n-type charge generation layer 410 and a p-type charge generation layer 420. The n-type charge generation layer 410 is disposed on the first stack 300 and may provide electrons to the first stack 300. The p-type charge generation layer 420 is disposed on the n-type charge generation layer 410 and may provide holes to the second stack 500.

The second stack 500 may be disposed on the p-type charge generation layer 420. The second stack 500 may also be disposed on the bank 150. That is, the second stack 500 may be disposed in the emission area EA and the non-emission area NEA.

The second stack 500 may include a second emission layer. The second emission layer may generate light. For example, the second emission layer may generate any one of red, green, and blue light, but is not limited thereto.

The second stack 500 may further include a material layer for assisting the second emission layer to generate light. For example, the second stack 500 may include a second hole transport layer, a hole block layer, a second electron transport layer, or the like. The second hole transport layer may assist holes provided in the p-type charge generation layer 420 to be easily transported to the second emission layer. In addition, the hole block layer may prevent holes injected into the second emission layer from leaking through the second electron transport layer. In addition, the second electron transport layer may assist electrons provided in the second electrode 600 to be easily transported to the second emission layer.

The second electrode 600 may be disposed on the second stack 500. The second electrode 600 may also be disposed on the bank 150. That is, the second electrode 600 may be disposed in the emission area EA and the non-emission area NEA.

The second electrode 600 may function as a cathode of the display device. That is, the second electrode 600 may provide electrons to the second stack 500.

Since the display device according to an embodiment of the present disclosure is configured in a top emission type, the second electrode 600 may include a transparent conductive material such as an indium tin oxide (ITO) or an indium zinc oxide (IZO) to transmit light emitted from the first stack 300 and the second stack 500 upward.

The encapsulation layer 160 may be disposed on the light emitting device OLED. The encapsulation layer 160 may compensate for a step difference caused by the light emitting device OLED. The encapsulation layer 160 may include an organic insulating material such as an acrylic resin, an epoxy resin, a phenolic resin, a polyamide resin, or a polyimide resin. The encapsulation layer 160 may be disposed in the entire emission area EA and the entire non-emission area NEA.

The black matrix 170, the color filter 180, and the second substrate 190 may be disposed on the encapsulation layer 160.

The second substrate 190 may be disposed in the emission area EA and the non-emission area NEA. The second substrate 190 may be made of glass or plastic, but is not limited thereto. Since the display device according to an embodiment of the present disclosure is made of a top emission type, a transparent material may be used as a material of the second substrate 190.

The black matrix 170 may be disposed between the second substrate 190 and the encapsulation layer 160. The black matrix 170 may be disposed in the non-emission area NEA. The black matrix 170 may expose a partial area of the second substrate 190. A width of the black matrix 170 may be less than or equal to a width of the bank 150.

The color filter 180 may be disposed between the second substrate 190 and the encapsulation layer 160. The color filter 180 may be disposed on a lower surface of the second substrate 190 exposed by the black matrix 170. That is, the color filter 180 may be disposed in the emission area EA.

The color filter 180 may transmit only light of a specific wavelength band. For example, the color filter 180 may transmit only anyone light of red, green, and blue.

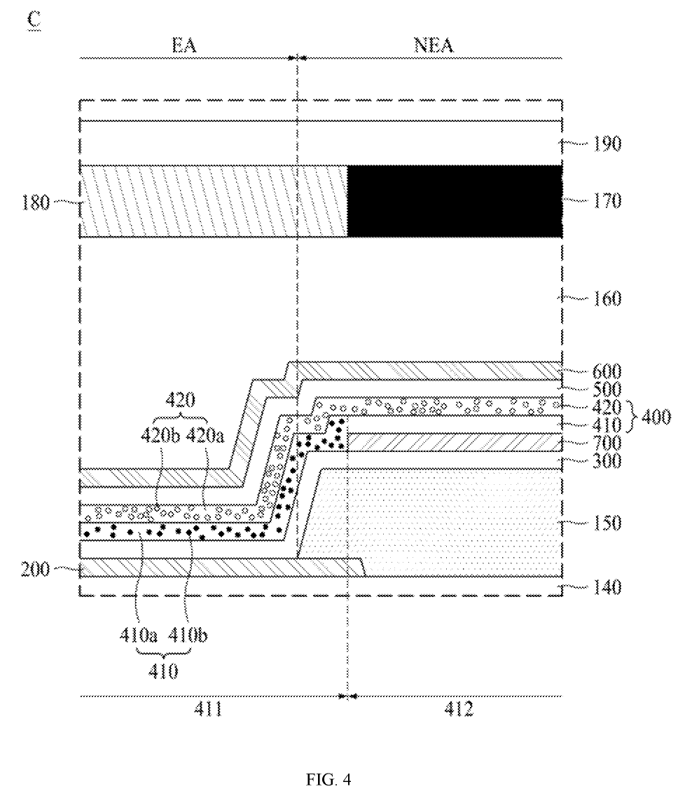

Meanwhile, referring to FIG. 3, a doping prevention layer 700 may be disposed inside the light emitting device OLED. This will be described in detail with reference to FIG. 4.

FIG. 4 is an enlarged view of an area C of FIG. 3. In detail, one side non-emission area NEA and a partial area of the emission area EA of the sub-pixel SP are illustrated. In addition, an upper area of the planarization layer 140 is illustrated.

As described above, the light emitting device OLED may include the first electrode 200, the first stack 300, the charge generation layer 400, the second stack 500, and the second electrode 600. In addition, the charge generation layer 400 may include the n-type charge generation layer 410 and the p-type charge generation layer 420.

The n-type charge generation layer 410 may include an n-type host material 410a and an n-type dopant material 410b. The n-type host material 410a may be disposed throughout the n-type charge generation layer 410, and the n-type dopant material 410b may be disposed in a partial area of the n-type charge generation layer 410. Furthermore, the n-type dopant material 410b may be distributed in the n-type host material 410a.

In this case, an area of the n-type charge generation layer 410 provided with the n-type dopant material 410b may be a doped region 411, and an area of the n-type charge generation layer 410 not provided with the n-type dopant material 410b may be an undoped region 412. That is, the doped region 411 and the undoped region 412 may be distinguished according to whether the n-type dopant material 410b is doped in the n-type charge generation layer 410. The doped region 411 and the undoped region 412 are disposed on the same layer and may be formed continuously.

The n-type host material 410a may include an organic material capable of transferring electrons. For example, the n-type host material 410a may include, but is not limited to, Alq3 (tris(8-hydroxyquinolino)aluminum), Liq (8-hydroxyquinolinolato-lithium), PBD (2-(4-biphenylyl)-5-(4-tert-butylphenyl)-1,3,4oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2',2-(1,3,5-benzenetriyl)-tris(1-phenyl-1-H-benzimidazole), oxadiazole, triazole, phenanthroline, benzoxazole, or benzothiazole, but is not limited to these compounds.

The n-type dopant material 410b may include an alkali metal. For example, the n-type dopant material 410b may include any one of lithium (Li), sodium (Na), potassium (K), or cesium (Cs), but is not limited thereto. Alternatively, the n-type dopant material 410b may include an alkaline earth metal. For example, the n-type dopant material 410b may include any one of magnesium (Mg), strontium (Sr), barium (Ba), radium (Ra), or ytterbium (Yb), but is not limited thereto.

Accordingly, the n-type charge generation layer 410 may provide electrons generated by the n-type dopant material 410b to the first stack 300 through the n-type host material 410a.

In this case, the doped region 411 and the undoped region 412 of the n-type charge generation layer 410 may be defined by a doping prevention layer 700.

Referring to FIG. 4, the doping prevention layer 700 may be disposed between the first stack 300 and the n-type charge generation layer 410. A lower surface of the doping prevention layer 700 may be in contact with an upper surface of the first stack 300, and an upper surface of the doping prevention layer 700 may be in contact with a lower surface of the n-type charge generation layer 410. In this case, an area of the n-type charge generation layer 410 that does not overlap the doping prevention layer 700 may be a doped region 411, and an area of the n-type charge generation layer 410 that overlaps the doping prevention layer 700 may be an undoped region 412. That is, the doping prevention layer 700 may be disposed between the first stack 300 and the undoped region 412.

The doping prevention layer 700 may include a fluorinated oligomer. The fluorinated oligomer is a material, having high chemical stability and having low surface energy. Accordingly, the fluorinated oligomer may have low binding properties with other materials. In particular, the fluorinated oligomer may have low binding properties with a metal having low binding energy.

As described above, the n-type dopant material 410b may include an alkali metal or an alkaline earth metal. Typically, an alkali metal or an alkaline earth metal is a metal having relatively low binding properties. That is, the n-type dopant material 410b may include a metal having low binding properties. Accordingly, the n-type dopant material 410b may not be deposited on the doping prevention layer 700. Accordingly, the n-type dopant material 410b may not be disposed in an area overlapping the doping prevention layer 700.

The doping prevention layer 700 may be disposed on a part of an upper surface of the first stack 300. Since the first stack 300 does not include a metallic material, the first stack 300 may not be affected by the doping prevention layer 700.

The doping prevention layer 700 may be disposed in the non-emission area NEA. As described above, the n-type charge generation layer 410 may provide electrons to the first stack 300 through the n-type host material 410a and the n-type dopant material 410b. Accordingly, the first stack 300 may generate light by using electrons provided from the n-type charge generation layer 410. Meanwhile, the doped region 411 may include the n-type dopant material 410b, but the undoped region 412 may not include the n-type dopant material 410b. Accordingly, a light efficiency of an area where the doped region 411 overlaps may be higher than a light efficiency of an area overlapping the non-doped region 412 in the light emitting diode OLED.

Accordingly, for light efficiency of the display device, the doped region 411 may be preferably disposed in the emission area EA, and the undoped region 412 may be preferably disposed in the non-emission area NEA. Accordingly, the doping prevention layer 700 defining the undoped region 412 may be preferably disposed in the non-emission area NEA.

Since the doping prevention layer 700 is disposed in the non-emission area NEA, the doping prevention layer 700 may be disposed in an area overlapping any one of the bank 150 and the black matrix 170. Alternatively, the doping prevention layer 700 may overlap both the bank 150 and the black matrix 170. In addition, FIG. 4 illustrates that the doping prevention layer 700 is not disposed on one side bank 150 and is disposed only on the other side bank 150, but is not limited thereto. For example, the doping prevention layer 700 may be disposed on both one side bank and the other side bank 150.

The p-type charge generation layer 420 may include a p-type host material 420a and a p-type dopant material 420b. The p-type host material 420a and the p-type dopant material 420b may be disposed in an entire area of p-type charge generation layer 420. In addition, the p-type dopant material 420b may be distributed in the p-type host material 420a.

The p-type host material 420a may include an organic material capable of transferring holes. For example, the p-type host material 420a may include NPD (N,N’-dinaphthyl-N,N'-diphenyl benzidine), (N, N'-bis(naphthalene-1-yl)-N, N'-bis(phenyl)-2,2'-dimethylbenzidine), TPD (N,N'-bis-(3-methylphenyl)-N,N'-bis-(phenyl)-benzidine), and MTDATA (4,4′,4-Tris(N-3-methylphenyl-N-phenyl-amino)-triphenylamine), but is not limited thereto.

The p-type dopant material 420b may include an organic material such as tetrafluoro- tetracyanoquinodimethane (F4-TCNQ), hexaazatriphenylene-hexacarbonitrile (HATCN), or a metal material such as V₂O₅, MoOₓ, or WO₃, but is not limited thereto.

That is, the p-type dopant material 420b may include a material having a characteristic different from a characteristic of the n-type dopant material 410b. Accordingly, the p-type dopant material 420b may not be affected by the doping prevention layer 700. That is, the p-type dopant material 420b may also be disposed at a position overlapping the doping prevention layer 700. Accordingly, the p-type host material 420a and the p-type dopant material 420b may be disposed on an entire area of an upper surface of the n-type charge generation layer 410. That is, the p-type dopant material 420b may be distributed over all areas of the p-type charge generation layer 420.

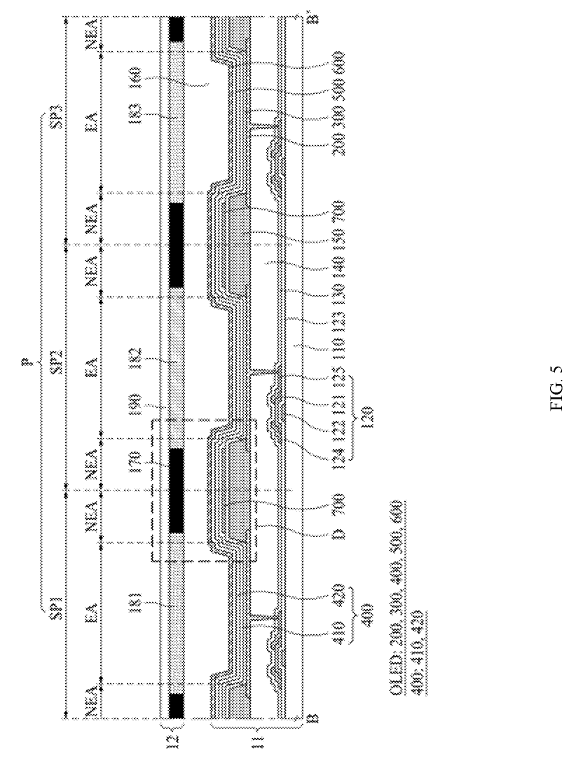

FIG. 5 is a cross-sectional view of one pixel P according to an embodiment of the present disclosure. Particularly, it is a cross-sectional view of one pixel P taken along line B-B′ illustrated in FIG. 2.

As described above, one pixel P may include a first sub-pixel SP1, a second sub-pixel SP2, and a third sub-pixel SP3.

The first sub-pixel SP1 may include a light emitting device OLED that generates red light and a first color filter 181 that transmits red light. Accordingly, the first sub-pixel SP1 may emit red light.

The second sub-pixel SP2 may include a light emitting device OLED that generates green light and a second color filter 182 that transmits green light. Accordingly, the second sub-pixel SP2 may emit green light.

The third sub-pixel SP3 may include a light emitting device OLED that generates blue light and a third color filter 183 that transmits blue light. Accordingly, the third sub-pixel SP3 may emit blue light.

First electrodes 200 of each of the first sub-pixel SP1, the second sub-pixel SP2, and the third sub-pixel SP3 may be spaced apart from each other. In addition, a bank 150 may be continuously disposed between the first sub-pixel SP1 and the second sub-pixel SP2. In addition, the bank 150 may be continuously disposed between the second sub-pixel SP2 and the third sub-pixel SP3.

A first stack 300, a charge generation layer 400, a second stack 500, and a second electrode 600 of each of the first sub-pixel SP1, the second sub-pixel SP2, and the third sub-pixel SP3 may be continuously disposed. In addition, a first emission layer disposed in the first stack 300 of each of the first sub-pixel SP1, the second sub-pixel SP2, and the third sub-pixel SP3 may be spaced apart from each other. In addition, a second emission layer disposed in the second stack 500 of each of the first sub-pixel SP1, the second sub-pixel SP2, and the third sub-pixel SP3 may be spaced apart from each other.

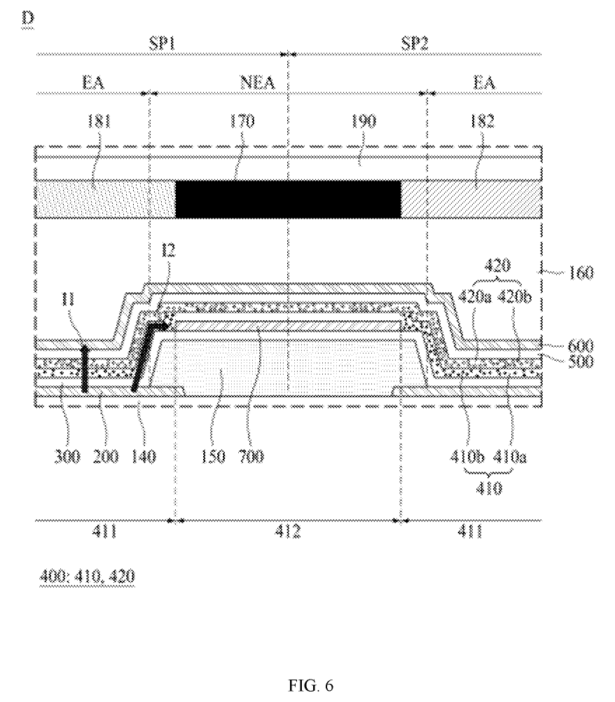

FIG. 6 is an enlarged view of an area D of FIG. 4. In detail, a boundary area between the first sub-pixel SP1 and the second sub-pixel SP2 is illustrated. In addition, an upper area of the planarization layer 140 is illustrated.

As described above, each of the first sub-pixel SP1 and the second sub-pixel SP2 may include an n-type charge generation layer 410 and a p-type charge generation layer 420. In addition, the n-type charge generation layer 410 may include a doped region 411 and an undoped region 412.

Referring to FIG. 6, the n-type charge generation layer 410 of the first sub-pixel SP1 and the n-type charge generation layer 410 of the second sub-pixel SP2 may be continuously disposed. Particularly, the undoped region 412 of the first sub-pixel SP1 and the undoped region 412 of the second sub-pixel SP2 may be continuously disposed in a boundary area between the first sub-pixel SP1 and the second sub-pixel SP2.

In this case, a doping prevention layer 700 may be disposed in the boundary area between the first sub-pixel SP1 and the second sub-pixel SP2. Accordingly, the undoped region 412 may be disposed in the boundary area between the first sub-pixel SP1 and the second sub-pixel SP2. That is, the n-type dopant material 410b may not be disposed in the boundary area between the first sub-pixel SP1 and the second sub-pixel SP2.

Generally, when a voltage is supplied to the first electrode 200 and the second electrode 600, a driving current may flow from the first electrode 200 to the second electrode 600. The first stack 300 and the second stack 500 may generate light by the driving current, and the light emitting device OLED may emit light. In this case, a lateral leakage current LLC may flow between neighboring sub-pixels SP.

As described above, the first stack 300, the charge generation layer 400, the second stack 500, and the second electrode 600 may be continuously disposed between neighboring sub-pixels SP. In this case, when the light emitting device OLED disposed in any one sub-pixel SP emits light, a lateral leakage current may flow to the light emitting device OLED disposed in the neighboring sub-pixel SP.

Specifically, when the light emitting device OLED of the first sub-pixel SP1 emits light, a first current I1 may flow from the first electrode 200 of the first sub-pixel SP1 toward the second electrode 600 of the first sub-pixel SP1. Accordingly, the light emitting device OLED of the first sub-pixel SP1 may emit light. By driving the first sub-pixel SP1, a second current I2, which is a lateral leakage current, may flow to the second sub-pixel SP2 adjacent to the first sub-pixel SP1.

As described above, the first stack 300, the charge generation layer 400, the second stack 500, and the second electrode 600 may be continuously disposed between the first sub-pixel SP1 and the second sub-pixel SP2. Accordingly, the second current I2 may flow to the second sub-pixel SP2 through a material layer continuously disposed in the first sub-pixel SP1 and the second sub-pixel SP2. In particular, the n-type charge generation layer 410 includes an n-type dopant material 410b that provides electrons. Accordingly, the second current I2 is highly likely to flow through the n-type charge generation layer 410.

However, the present disclosure discloses that the undoped region 412 is disposed in a boundary area between the first sub-pixel SP1 and the second sub-pixel SP2 by the doping prevention layer 700. Since the undoped region 412 includes only the n-type host material 410a, a possibility of current flowing of the undoped region 412 may be lower than a possibility of current flowing of the doped region 411. That is, the second current I2 may not flow to the second sub-pixel SP2 due to the undoped region 412. Therefore, the present disclosure may reduce an occurrence of the lateral leakage current flowing between the adjacent sub-pixels SP.

A display device according to an embodiment of the present disclosure includes a plurality of sub-pixels including an emission area and a non-emission area surrounding the emission area, and each of the plurality of sub-pixels include a first electrode disposed on the substrate in the emission area, a first stack disposed on the first electrode, a doping prevention layer disposed on the first stack, and an n-type charge generation layer disposed on the doping prevention layer. In addition, the n-type charge generation layer includes a doped region including an n-type dopant material and an undoped region not including the n-type dopant material. In addition, the doping prevention layer does not overlap the doped region and overlaps the undoped region.

In the display device according to an embodiment of the present disclosure, the doped region and undoped region are disposed on a same layer.

In the display device according to an embodiment of the present disclosure, the doped region and undoped region are continuously formed.

In the display device according to an embodiment of the present disclosure, the doped region is disposed in the emission area and the undoped region is disposed in the non-emission area.

In the display device according to an embodiment of the present disclosure, an upper surface of the doping prevention layer is in contact with a lower surface of the n-type charge generation layer, and a lower surface of the doping prevention layer is in contact with an upper surface of the first stack.

In the display device according to an embodiment of the present disclosure, the doping prevention layer is disposed between the undoped region and the first stack.

In the display device according to an embodiment of the present disclosure, the doping prevention layer is disposed in the non-emission area.

The display device according to an embodiment of the present disclosure further comprises a bank disposed on the substrate in the non-emission area, wherein the doping prevention layer overlaps the bank.

In the display device according to an embodiment of the present disclosure, the doping prevention layer includes a fluorinated oligomer.

In the display device according to an embodiment of the present disclosure, the n-type dopant materials include an alkali metal or an alkaline earth metal.

The display device according to an embodiment of the present disclosure further comprises a p-type charge generation layer disposed on the n-type charge generation layer, wherein a p-type dopant material is distributed in all areas of the p-type charge generation layer.

In the display device according to an embodiment of the present disclosure, an area where the p-type dopant material is disposed overlaps with the doping prevention layer in the p-type charge generation layer.

In the display device according to an embodiment of the present disclosure, the plurality of sub-pixels includes a first sub-pixel and a second sub-pixel adjacent to each other, and a n-type charge generation layer of the first sub-pixel and a n-type charge generation layer of the second sub-pixel are continuously disposed.

In the display device according to an embodiment of the present disclosure, an undoped region of the first sub-pixel and an undoped area of the second sub-pixel are continuously disposed in a boundary area between the first sub-pixel and the second sub-pixel.

In the display device according to an embodiment of the present disclosure, the doping prevention layer is disposed in a boundary area between the first sub-pixel and the second sub-pixel.

The display device according to an embodiment of the present disclosure further comprises a bank disposed on the substrate in a boundary area between the first sub-pixel and the second sub-pixel, wherein the doping prevention layer overlaps the bank.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims, and it is intended that all variations or modifications derived from the meaning, scope and equivalent concept of the claims fall within the scope of the present disclosure.

What is claimed is:

1. A display device comprising:
a plurality of sub-pixels comprising an emission area and a non-emission area surrounding the emission area,
wherein each of the plurality of sub-pixels comprises:
a first electrode disposed on a substrate in the emission area;
a first stack disposed on the first electrode;
a doping prevention layer disposed on the first stack; and
an n-type charge generation layer disposed on the doping prevention layer,
wherein the n-type charge generation layer comprises a doped region comprising an n-type dopant material and an undoped region not including the n-type dopant material, and
wherein the doping prevention layer does not overlap with the doped region and overlaps with the undoped region.

2. The display device of claim 1, wherein the doped region and the undoped region are disposed on a same layer.

3. The display device of claim 1, wherein the doped region and the undoped region are continuously formed.

4. The display device of claim 1, wherein the doped region is disposed in the emission area, and wherein the undoped region is disposed in the non-emission area.

5. The display device of claim 1, wherein an upper surface of the doping prevention layer is in contact with a lower surface of the n-type charge generation layer, and wherein a lower surface of the doping prevention layer is in contact with an upper surface of the first stack.

6. The display device of claim 1, wherein the doping prevention layer is disposed between the undoped region and the first stack.

7. The display device of claim 1, wherein the doping prevention layer is disposed in the non-emission area.

8. The display device of claim 1, further comprising a bank disposed on the substrate in the non-emission area, wherein the doping prevention layer overlaps with the bank.

9. The display device of claim 1, wherein the doping prevention layer comprises a fluorinated oligomer.

10. The display device of claim 1, wherein the n-type dopant material is selected from an alkali metal, an alkaline earth metal, and a combination thereof.

11. The display device of claim 1, further comprising a p-type charge generation layer disposed on the n-type charge generation layer, wherein a p-type dopant material is distributed in all areas of the p-type charge generation layer.

12. The display device of claim 11, wherein an area where the p-type dopant material is disposed overlaps with the doping prevention layer in the p-type charge generation layer.

13. The display device of claim 1, wherein the plurality of sub-pixels comprises a first sub-pixel and a second sub-pixel adjacent to each other, and
wherein a n-type charge generation layer of the first sub-pixel and a n-type charge generation layer of the second sub-pixel are continuously disposed.

14. The display device of claim 13, wherein an undoped region of the first sub-pixel and an undoped area of the second sub-pixel are continuously disposed in a boundary area between the first sub-pixel and the second sub-pixel.

15. The display device of claim 13, wherein the doping prevention layer is disposed in a boundary area between the first sub-pixel and the second sub-pixel.

16. The display device of claim 13, further comprising a bank disposed on the substrate in a boundary area between the first sub-pixel and the second sub-pixel, wherein the doping prevention layer overlaps with the bank.
